(19) United States
(12) Patent Application Publication
(10) Pub. No.: US 2020/0371141 A1
(43) Pub. Date: Nov. 26, 2020

(54) MEASUREMENT SIGNAL DEVICE FOR A PHYSICAL VARIABLE

(71) Applicant: Phoenix Contact GmbH & Co. KG, Blomberg (DE)

(72) Inventor: Martin Jankowski, Seelze (DE)

(21) Appl. No.: 16/635,335

(22) PCT Filed: Jul. 27, 2018
(86) PCT No.: PCT/EP2018/070392

§ 371 Date: Jan. 30, 2020

(30) Foreign Application Priority Data
Aug. 1, 2017 (BE) BE2017/5538

(51) Int. Cl. G01R 22/06; G01D 4/02

(52) U.S. Cl. CPC G01R 22/063; G01D 4/02

(57) ABSTRACT

Disclosed is a measurement signal device for a physical variable, comprising: a sensor connection configured to provide the physical variable, wherein a measurement value is based on the physical variable; a processor configured to assign a handling instruction for electronically handling the measurement value to the measurement value, the processor being further configured to encode the measurement value together with the handling information in a graphically representable code; and a display configured to graphically display the graphically representable code.

### CROSS-REFERENCE TO RELATED APPLICATIONS

The present disclosure is the national stage entry under 35 U.S.C. §371 of International Application No. PCT/EP2018/070392, filed 27 Jul. 2018, and entitled “Measurement Signal Device for a Physical Variable,” and claims the benefit of Belgian Patent Application No. BE2017/5538, filed 1 Aug. 2017, and entitled “Messignalgerät für eine physikalische Größe.” Each of these applications is incorporated herein by reference in its entirety.

### BACKGROUND

The present disclosure relates to a measurement signal device for a physical variable, in particular electrical energy.

A measurement signal device can usually display at least one measurement value via an optical display and update the measurement value in an interval. The at least one measurement value can be recordable by a processing unit via a communication interface of the measurement signal device. A disadvantage of this type of measurement value detection is the increased component expenditure, which may be necessary for the processing unit and/or the communication interface. The measurement value can also be detected visually, by means of a reading by a user of the measurement signal device, the reading of the measurement value having the disadvantage of an increased susceptibility to errors.

### SUMMARY

It is the object of the present disclosure to provide an improved measurement signal device.

This object is solved by the features of the independent claims. Advantageous examples are the subject of the dependent claims, the description and the accompanying figures.

The present disclosure is based on the knowledge that the above object can be achieved by a measurement signal device which provides a measurement value as part of a digital code via a display. The code also has handling instructions relating to the measurement value, which can be used by a reading device to process the measurement value. The code can be optically represented by the display as a graphic code, in particular as a two-dimensional code, QR code and/or binary code.

As a result, the measurement value can be detected efficiently and error-free from the display of the measurement signal device, in particular with the aid of a camera integrated in the reading device.

According to a first aspect, the disclosure relates to a measurement signal device for a physical variable, with a sensor connection for providing the physical variable in order to obtain a measurement value, a processor which is configured to assign a handling instruction for electronically handling the measurement value to the measurement value, wherein the processor is further configured to encode the measurement value together with the handling instruction in a graphically representable code, and a display which is adapted to graphically represent the graphically representable code.

In one example, the measurement signal device comprises a sensor for detecting the physical variable, the sensor being electrically connected to the sensor connection for providing the physical variable or being part of the sensor connection. In this way, additional sensors can be connected particularly easily.

In one example, the measurement signal device comprises a communication interface for receiving the physical variable, the communication interface being electrically connected to the sensor connection for providing the physical variable. The communication interface can be wired or wireless.

The measurement signal device can convert the physical variable into a discrete measurement value, which can be provided to the processor in digital form. The measurement signal device can also be adapted for the periodic detection of the physical variable, the display of the graphically representable code being updatable by the display each time the physical measurement variable is detected. In particular, with each detection of the physical variable, a new graphically representable code can be generated, which can contain the most current measurement value. Furthermore, the graphically representable code can have a plurality of measurement values, wherein the plurality of measurement values can have been detected by the sensor over a specific period of time.

In one example, the handling instruction comprises an instruction for sending the measurement value to a network address and/or a network address.

The network address can be a reference to a website, an email address and/or a mobile phone number. The handling instruction can cause the measurement value to be passed on to a website by a reading device, wherein the measurement value can be integrated into the content of the website and the content of the website can be represented by a display of the reading device. The handling instruction can trigger the sending of a message, which comprises at least the measurement value, by the reading device. The message can in particular be a text message, which can be sent to a mobile phone number and/or an email address.

The handling instruction can refer to contents which are stored in a network and/or on the reading device. In particular, this content can provide information relating to the mode of operation, the scope of functions, the configuration options of the measurement signal device and/or the configuration of the measurement signal device.

Sending the measurement value to a network address by the reading device has the advantage that an infrastructure for, in particular, central recording of the measurement value can only be provided by the reading device for the period of recording the graphically representable code. The infrastructure can in particular be provided by the reading device, which can have a network connection. The device expenditure and/or the costs for a central, in particular network-dependent, detection of the physical variable can thus be advantageously reduced.

In one example, the handling instruction also has device information about the measurement signal device, in particular information about the type and/or the physical unit of the physical variable.

The device information can provide the specification of the sensor and/or information relating to the detection of the physical measured variable. These can comprise, for example, a tolerance range of the measurement value, an accuracy specification of the measurement value, a minimum and/or a maximum value of the physical variable that can be detected by the sensor, a temporal resolution of the measurement value, a period of time for the detection of the physical variable and/or a format specification of the measurement value. This has the advantage that the measurement value represents a precise specification of the physical variable and errors in the processing of the measurement value, in particular by the reading device and/or in the interpretation of the measurement value by a user, can be avoided. In particular, reading errors and/or conversion errors in the unit of the measurement value can be avoided.

In one example, the measurement signal device further comprises a user interface for configuring the handling instruction.

A user can interact with the measurement signal device via the user interface. The processor can be adapted to process control commands and/or user inputs, which can be entered, for example, via keys, in order to carry out an action and, in particular, to display a feedback regarding the control commands and/or the user inputs by means of the display.

The user interface can also be an acoustic and/or optical interface of the measurement signal device, so that acoustic and/or optical signals can be detected and processed by the measurement signal device.

Due to the configurability of the handling instruction, the information provided via the graphically representable code can be adapted to the requirements of a user, so that the measurement signal device can be used universally and the scope of application of the measurement signal device can be advantageously enlarged.

In one example, the content, in particular one or more executable functions, of the handling instruction can be entered or configured via the user interface.

This has the advantage that the processing, in particular an evaluation and/or a representation of the measurement value, can be configured and can also be changeable via the user interface during operation of the measurement signal device.

In one example, the user interface is a touch-sensitive interface or an input interface or a wireless interface, in particular an RFID interface or an NFC interface.

By designing the user interface as an electronic interface, the advantage is achieved that the configuration of the measurement signal device, for example, can be carried out remotely, for example, not on site at the measurement signal device, for example from an external data processing device. Furthermore, a particularly predefined configuration can be transmitted to the measurement signal device via the electronic interface. As a result, in particular a plurality of measurement signal devices can be operated with an identical configuration, wherein the occurrence of an error caused by the transmission of the configuration can be advantageously reduced by the electronic transmission of the configuration.

In one example, the user interface comprises a haptic control element, which is adapted to convert a haptic user input into electronic control signals for configuring the handling instruction, the format of the measurement value and/or the graphically representable code and to provide it to the processor.

This has the advantage that the configuration of the measurement signal device can be carried out directly by the user via the haptic control element on the measurement signal device and/or without any further device expenditure.

In one example, a property of the graphically representable code is configurable via the user interface, and the processor is adapted to generate the graphically displayable code according to the entered property.

This achieves the advantage that the type of the graphically displayed code can be adapted, in particular to the specifications of the reading device. For example, the reading device can be limited to reading out a specific graphically representable code, so that by adapting the graphically representable code, the reading of the graphically representable code can be used with such a reading device. The format and/or the representation of the code can also be configured.

In addition, this has the advantage that the display of the graphically representable code can be adapted to the specifications of the reading device. This adaptation can include, for example, the size, position, color and/or brightness of the graphically representable code and/or the display itself.

In one example, the graphically representable code is a one-dimensional or a two-dimensional and/or a matrix code, in particular a QR code and/or a binary code.

This has the advantage that the graphically representable code can be captured efficiently and with a low reading error rate by a camera. The reading error rate can be scalable, in particular due to the type of coding. Furthermore, the graphically representable code can comprise checksums and/or redundant or additional data, so that an incorrect detection of the graphically representable code by the reading device can be determined and/or corrected.

The measurement signal device can in particular be adapted to generate and display a plurality of different matrix codes, for example QR codes, data matrix codes, maxi codes and/or Aztec codes. Furthermore, one-dimensional binary codes, in particular bar codes, can be generated by the processor and displayed by the display. It may be necessary to change the graphical code used when changing the reading device. An exchange of the measurement signal device does not have to take place additionally, only the configuration of the graphically representable code can be adapted. Furthermore, a new code format can be provided to the measurement signal device via the user interface, so that future, graphically representable codes can be also generated and displayed by the measurement signal device.

In one example, the physical variable is electrical energy or electrical power.

In one example, the measurement signal device is adapted to record a plurality of physical variables and to process, for example, add up the recorded plurality of physical variables in order to obtain the measurement value.

For example, the recorded plurality of the physical variables can be multiplied, added up and/or processed by means of a Fourier transformation. This can be used in particular to detect an electrical current, an electrical voltage, an electrical power and/or an electrical energy.

This achieves the advantage that the measurement signal device can be used as an energy meter for measuring an electrical energy consumed by a consumer. In particular, the measurement signal device can provide an actual fluid and/or energy consumption value and an accumulated fluid and/or energy consumption value.

In one example, the sensor is adapted to detect a plurality of physical variables in order to obtain a plurality of measurement values. This has the advantage that a measurement signal device can be used to record a plurality of physical variables and/or the same measurement signal device can be used to record different physical variables at different locations. The plurality of physical variables can in particular include electromagnetic variables and/or variables of the surroundings of the measurement signal device. In particular, the plurality of physical variables can include a number of the following physical variables: amount of heat, electrical current, electrical power, electrical voltage, flow velocity of a fluid, temperature, pressure, brightness, air humidity, amount of precipitation, energy consumption, accumulated flow rate of a fluid, electrical energy.

In one example, a number of measurement values of the plurality of measurement values and/or a plurality of handling instructions for electronically handling the number of measurement values for coding in the graphically representable code can be selected via the user interface. This has the advantage that not only a single measurement value, but a plurality of measurement values can be recorded and processed by the reading device using the graphically represented code. The measurement signal device can also be adapted to provide a plurality of measurement values of a physical value, wherein the respective measurement values of the plurality of measurement values can be recorded at different locations. For example, in the electrical power measurement of a plurality of consumers, one measurement signal device can replace a plurality of measurement signal devices.

In one example, the handling instructions and/or the measurement value are formed by an alphanumeric character string, the alphanumeric character string being able to be represented graphically by the display.

The graphically representable code represents an efficient form of a machine-readable graphical information, so that the graphically representable code can advantageously be used for reading in particular by the electronic reading device. The information comprised by the graphically representable code may not be directly decodable by a user viewing the display and/or with the aid of additional devices and/or aids. It is therefore advantageous to display the measurement value and/or the handling instructions additionally and/or alternating with the representation of the graphically representable code as an alphanumeric character string by means of the display. This achieves the advantage that the measurement value can be read directly from the measurement signal device by the user.

The alphanumeric character string can in particular include the measurement value and the physical unit of the measurement value. The alphanumeric character string can be updated periodically, in particular with a new detection of the physical measured variable. The update interval can be limited to a minimum value in order to facilitate reading by the user.

In one example, the processor is adapted to encrypt the measurement value and/or the handling instruction and to encode the encrypted measurement value and/or the encrypted handling instruction in the graphically representable code.

This has the advantage that, in particular, security-relevant measurement values and/or security-relevant handling instructions can be protected against unauthorized access. The format of the graphically representable code used can correspond to an open standard or a generally known specification, so that only the coding of the measurement value and/or the handling instructions can provide reduced protection against unauthorized access to the measurement value and/or the handling instructions. Through the encryption, the measurement signal device can be coupled to a specific reading device, which is adapted to decrypt the encrypted measurement value and/or the encrypted handling instruction.

Furthermore, encryption has the advantage that the data comprised by the graphically representable code cannot be accessible to the reading device. The reading device can read out the graphically representable code and store the data contained therein, in particular in accordance with the handling instructions, in an internal memory and/or pass it on to the external data processing device. It may therefore be advantageous to encrypt the measurement value and to transmit the handling instructions unencrypted by means of the graphically representable code.

In one example, the processor is adapted to make the graphically representable code electrically, in particular wirelessly, transferable to a reading device.

The wireless transmission can in particular be a radio transmission which is based on a short-range or long-distance radio standard. In particular, the radio transmission can be implemented by a WLAN, Bluetooth, NFC, UMTS, LTE, and/or 5G connection. This achieves the advantage that larger distances than in the case of an optical detection of the graphically representable code may be possible between the reading device and the measurement signal device. Furthermore, detection by means of radio transmission can make it possible to read the measurement value if the display of the measurement signal device is arranged to be optically inaccessible to the optical detection device of the reading device.

According to a second aspect, the disclosure relates to a reading device for reading out a code that can be graphically represented by means of a display, which has an indication of a measurement value of a physical variable and a handling instruction for electronic handling of the measurement value, with an optical detection device, in particular an image camera, which is adapted to optically detect the graphically representable code, a processor which is adapted to decode the graphically representable code in order to obtain the measurement value and the handling instruction, the reading device being adapted to handle the measurement value in accordance with the handling instruction.

The reading device can in particular be a portable user terminal, in particular a smart

phone or tablet. The processor of the reading device can also be adapted to execute a software program which realizes reading out the graphically representable code from the measurement signal device, decoding the graphically representable code, displaying the data contained in the graphically representable code and/or executing the handling instruction. The reading device can have a memory in order to store the measurement value and/or the handling instruction.

In one example, the handling instruction has an instruction for sending the measurement value via a communication network to a network address, the reading device having a communication interface which is adapted to send the measurement value to the network address via the communication network, in particular wirelessly or by wire.

The reading device can have a network interface for connection to a wired and/or wireless communication network, in particular a mobile radio network, in order to forward the graphically representable code, the measurement value and/or the handling instruction to the external data processing device.

The measurement signal device can generate a discrete measurement value at periodic time intervals when the physical variable is detected, wherein a previously generated measurement value is no longer available for integration into the graphically representable code. Within a detection period, the processor can convert the discrete measurement value into the graphically representable code with the handling instruction.

Furthermore, the measurement signal device can have a memory in which the measurement values of the physical measured variable, which in particular are recorded periodically, can be stored.

### BRIEF DESCRIPTION OF THE DRAWINGS

Further examples are explained with reference to the attached figures. They show:

FIG. 1 shows a measurement signal device in one example;

FIG. 2 shows a measurement signal device and a readout device in one example; and

FIG. 3 shows a measurement signal device and a readout device in one example.

### DETAILED DESCRIPTION

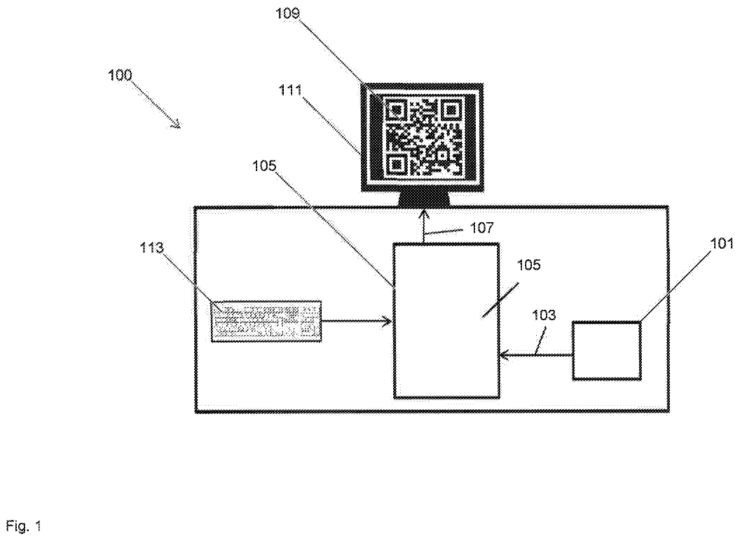

FIG. 1 shows a schematic representation of the measurement signal device 100 for a physical variable, with a sensor connection 101 for recording the physical variable in order to obtain a measurement value 103, a processor 105 which is adapted to assign the measurement value 103 to a handling instruction 107 for electronic handling of the measurement value 103, wherein the processor 105 is further configured to code the measurement value 103 together with the handling instruction 107 into a graphically representable code 109, and a display 111, which is adapted to graphically represent the graphically representable code 109.

Furthermore, the measurement signal device 100 comprises a user interface 113 for configuring the handling instruction 107. The user interface 113 is in particular a haptic control element, for example a keyboard, a keypad or a touch-sensitive surface. The user interface 113 can be connected to the display 111 in order to display user input entered via the user interface 113 on the display 111.

The user interface 113 is adapted to convert a user input into electronic control signals for configuring the handling instruction 107, the format of the measurement value 103 and/or the graphically representable code 109. Furthermore, a property of the graphically representable code 109 can be configured via the user interface 113, the processor 105 being adapted to generate the graphically representable code 109 in accordance with the entered property.

In addition to or instead of the haptic control element, an electronic or optical user interface can be provided. A wired or a wireless connection between a user terminal and the measurement signal device 100 can be realized via the electronic or optical user interface and the user input can be transmitted to the processor 105 via this connection.

The electronic user interface 113 can be a wireless interface, in particular an RFID interface or an NFC interface.

The content, in particular one or more executable functions, of the handling instruction 107 can be entered or configured via the user interface 113.

With the user input, the format and/or the type of the graphically representable code 109, the content of the graphically representable code 109 and/or the representation of the graphically representable code 109 can be configured by the display 111. In this way, device-specific and/or user-specific information and/or functions can be integrated in the graphically represented code 109.

The graphically representable code 109 is a two-dimensional code which is composed of areas of different brightness and/or different colors. The areas are arranged in a regular

grid. The graphically representable code 109 is a matrix code, and the matrix code can be a QR code.

In addition to the matrix code, an alphanumeric character string 201 can be shown on the display 111, which contains the measurement value 103 and, for example, an abbreviation and/or a symbol for the physical unit of the measurement value 103.

The display 111 is a screen, the number of pixels on the screen corresponding at least to the number of elements of the two-dimensional code 109 in order to completely display the two-dimensional code 109. Furthermore, the color and/or contrast difference between the areas is high enough to be recorded by an external camera, so that the individual areas of the two-dimensional code 109 can be recorded separately.

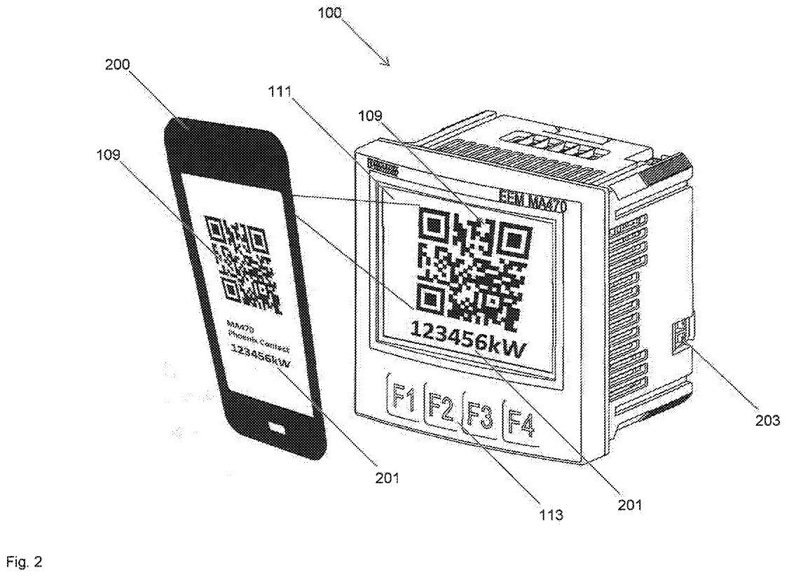

FIG. 2 shows a schematic illustration of the measurement signal device 100 for a physical variable, with a display 111 which is adapted to graphically represent the graphically representable code 109 and with a user interface 113 for configuring the handling instruction. Furthermore, a reading device 200 for reading out a code 109 that can be graphically represented by means of a display 111 is shown. The graphically representable code 109 has information about a measurement value 103 of a physical variable and a handling instruction 107 for the electronic handling of the measurement value 103. The reading device 200 has an optical detection device, in particular an image camera, which is adapted to optically detect the graphically representable code 109, and a processor which is adapted to decode the graphically represented code 109 in order to obtain the measurement value 103 and the handling instruction 107. The reading device 200 is adapted to handle the measurement value 103 in accordance with the handling instruction 107.

Furthermore, a method for detecting the graphically representable code 109 by the reader 200 is shown, which detects the graphically representable code 109 with an image camera integrated in the reader 200 and decodes the graphically representable code 109 by means of the processor of the reader 200 to obtain the measurement value 103 and/or the handling instruction 107. The processor of the reading device 200 can be adapted to decrypt an encrypted measurement value and/or an encrypted handling instruction 107.

The reading device 200 has a display which can represent the graphically representable code 109, the measurement value 103 and/or the handling instruction 107. The reading device 200 is a smartphone which enables a message with the measurement value 103 to be sent out in accordance with the handling instruction 107 via a wired and/or wireless network, in particular a mobile radio network.

The graphically representable code 109 is a two-dimensional, binary code, in particular a QR code. The two-dimensional, binary code consists of a square matrix of symbol elements. These symbol elements are in particular squares which have a different color and/or brightness and are in particular black or white.

A position marker in each of three of the four corners of the square describes the orientation of the graphically representable code 109. The data comprised by the graphically representable code 109, in particular the measurement value 103 and the handling instruction 107, can be protected by an error-correcting code. As a result, if part of the graphically representable code 109 is lost, for example up to 30% of the graphically representable code 109, the data can still be decoded from the graphically representable code 109 without loss. Between the three position marks there is a line of a sequence of alternating bits, which defines the matrix. The symbol elements can be arranged in a square matrix with a width of at least 21 and for example a maximum of 177 symbol elements. An edge zone can be defined which contains no user data and is, for example, at least 4 elements wide. A larger amount of data can be divided into several, for example up to 16 individual, graphically representable codes 109.

The alphanumeric character string 201 can be represented by the display 111 simultaneously or alternately with the graphically representable code 109.

The user interface 113 is formed by four operating elements, which have the designations F1, F2, F3 and F4 and are arranged in a row below the display 111. The control elements can in particular be mechanical, capacitive and/or resistive buttons or switches. The display 111 and the operating elements are arranged in a side face of a housing which comprises the sensor connection 101 and the processor 105. The housing can be an electrical connection unit 203 for the power supply of the measuring signal device 100 and/or the electrical supply of a measurement signal to the sensor 101.

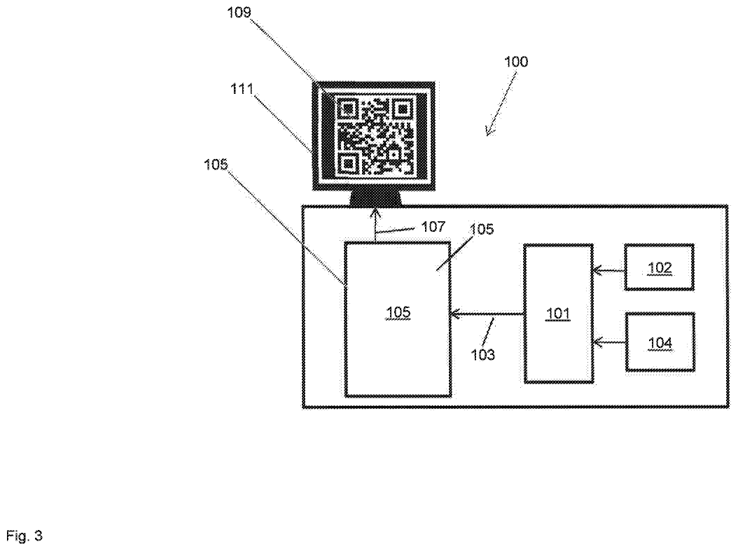

FIG. 3 shows the measurement signal device 100 in one example, which furthermore has a sensor 102 for detecting the physical variable, the sensor being electrically connected to the sensor connection 101 for providing the physical variable. Optionally, several sensors 102 can be provided for the detection of different physical variables, which are electrically connected or connectable to the sensor connection 101.

FIG. 3 also shows an element 104, which can be a communication interface, which can replace the sensor or is provided together with the sensor 102 in order to provide the physical variable or a further physical variable. The communication interface 104 can be wired, for example Ethernet, USB, or wireless, for example WLAN.

However, element 104 can also be a further sensor for detecting a further physical variable.

### LIST OF REFERENCE SIGNS

100 measurement signal device

101 sensor connection

102 sensor

103 measurement value

104 communication interface

105 processor

107 handling instruction

109 graphically representable code

111 display

113 user interface

200 reading device

201 alphanumeric string

203 connection unit

What is claimed is:

1. A measurement signal device for a physical variable, comprising:
a sensor connection configured to provide the physical variable, wherein a measurement value is based on the physical variable;
a processor configured to assign a handling instruction for electronically handling the measurement value to the measurement value, the processor being further configured to encode the measurement value together with the handling instruction in a graphically representable code; and
a display configured to graphically display the graphically presentable code.

2. The measurement signal device according to claim 1, wherein the handling instruction comprises an instruction for sending the measurement value to a network address.

3. The measurement signal device according to claim 1, wherein the handling instruction further comprises device information about the measurement signal device.

4. The measurement signal device according to claim 1, further comprising a user interface for configuring the handling instruction.

5. The measurement signal device according to claim 4, wherein one or more executable functions of the handling instruction are entered or configured via the user interface.

6. The measurement signal device according to claim 4, wherein the user interface is a touch-sensitive interface or an input interface or a wireless interface.

7. The measurement signal device according to claim 4, wherein a property of the graphically representable code is configurable via the user interface, and wherein the processor is adapted to display the graphically representable code according to the entered property.

8. The measurement signal device according to claim 1, wherein the graphically representable code comprises one or more of: a one-dimensional code, or a two-dimensional code, or a matrix code, or a binary code.

9. The measurement signal device according to claim 1, wherein the physical variable is electrical energy or electrical power.

10. The measurement signal device according to claim 1, wherein the processor is adapted to record a plurality of physical variables and to process the recorded plurality of physical variables in order to obtain the measurement value.

11. The measurement signal device according to claim 1, wherein one or more of the handling instruction or the measurement value is formed by an alphanumeric character string, wherein the alphanumeric character string can be graphically represented by the display.

12. The measurement signal device according to claim 1, wherein the processor is adapted to encrypt the measurement value or the handling instruction and to encode the encrypted measurement value or the encrypted handling instruction in the graphically representable code.

13. The measurement signal device according to claim 1, wherein the processor is adapted to provide the graphically representable code electrically or wirelessly to a reading device.

14. The measurement signal device according to claim 1, further comprising a sensor for detecting the physical variable, the sensor being electrically connected to the sensor connection configured to provide the physical variable, and further comprising a communication interface for receiving the physical variable, wherein the communication interface is electrically connected with the sensor connection to provide the physical variable.

15. A reading device for reading out a graphically representable code, comprising:
an optical detection device adapted to optically detect the graphically representable code, wherein the graphically representable code is configured to be graphically represented on a display and comprises information about a measurement value of a physical variable and a handling instruction for electronic handling of the measurement value; and
a processor adapted to decode the graphically representable code to obtain the measurement value and the handling instruction;
wherein the reading device is adapted to handle the measurement value in accordance with the handling instruction.

16. The measurement signal device of claim 3, wherein the device information about the measurement signal device comprises one or more of: an indication of a type of the physical variable or an indication of a physical unit of the physical variable.

17. The measurement signal device of claim 6, wherein the wireless interface comprises one or more of: a radio frequency identification (RFID) interface or a near field communications (NFC) interface.

18. The measurement signal device of claim 8, wherein the matrix code comprises a quick response (QR) code.
